(19) United States
(12) Patent Application Publication
(10) Pub. No.: US 2022/0318132 A1
(43) Pub. Date: Oct. 6, 2022

(54) SOFTWARE-ASSISTED SPARSE MEMORY

(71) Applicant: Intel Corporation, Santa Clara, CA (US)

(72) Inventors: Thomas WILLHALM, Sandhausen (DE); Francesc GUIM BERNAT, Barcelona (ES); Karthik KUMAR, Chandler, AZ (US)

(21) Appl. No.: 17/847,026

(22) Filed: Jun. 22, 2022

(51) Int. Cl. G06F 12/02

(52) U.S. Cl. CPC G06F 12/023

(57) ABSTRACT

Methods and apparatus for software-assisted sparse memory. A processor including a memory controller is configured to implement one or more portions of the memory space for memory accessed via the memory controller as sparse memory regions. The amount of physical memory used for a sparse memory region is a fraction of the address range for the sparse memory region, where only non-zero data are written to the physical memory. Mechanisms are provided to detect memory access requests for memory in a sparse memory region and perform associated operations, while non-sparse memory access operations are performed when accessing memory that is not in a sparse memory region. Interfaces are provided to enable software to request allocation of a new sparse memory region or allocate sparse memory from an existing sparse memory region. Operations associated with access to sparse memory regions include detecting whether data for read and write request are all zeros.

### BACKGROUND INFORMATION

Processing large arrays with relatively sparse data (i.e., most values are ‘0’s) has seen increasing usages in various domains, such as machine learning (ML), artificial intelligence (AI), graph analytics, etc. For example, in machine learning and AI domains relating to speech recognition or medical diagnostics the training data are generally very sparse and the training data sets may be very large (on the order of 10's of Gigabytes upwards to Terabytes). Graph representations may also employ sparse matrices, such as illustrated in FIG. 1.

Since sparse matrices have a lot of zeros, significant effort has been expended in software to optimize representations to handle storage of these zeros efficiently. For example, some of the different software-based storage formats for sparse matrix representations include compresses sparse row (CSR), dynamic compressed row (DCSR), and Hybrid ellpack (HYB). There are also schemes that are built into popular languages, such as Python, and various ML/AL frameworks. The techniques generally target some form of efficient software-based indexed representations, with hash-based lookups to organize and retrieve data from sparse matrices.

While having these representations in software can save memory capacity (which is a first order constraint for these kinds of applications, especially in parts of the memory hierarchy closer to the CPU)—there are heavy processing overheads in converting formats, especially for processing the data or operating on the data.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified

FIG. 1 is a diagram illustrating an example of a sparse matrix used to represent a graph,

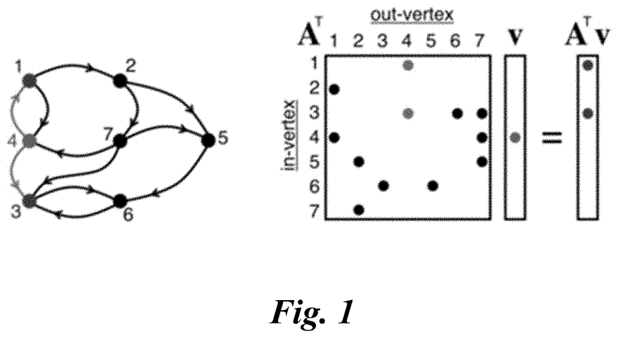

FIG. 2 is a diagram of a platform/system architecture illustrating aspects of the hardware logic used to implement sparse memory operations, according to one embodiment;

FIG. 3 is a diagram of a memory controller configured to implement logic and associated data structures to facilitate access to sparse memory and conventional memory, according to one embodiment;

FIGS. 4a-4c illustrate how a Bloom filter employing multiple hash algorithms and a single-dimension bit vector operates;

FIGS. 5a-5c illustrate how a Bloom filter employing multiple hash algorithms and respective bit vectors operates;

FIG. 6 is a diagram illustrating an example of a Bloom filter hierarchy, according to one embodiment;

FIG. 7 is a flowchart illustrating operations and logic implemented by a Bloom filter hierarchy, according to one embodiment; and

FIG. 8 is a flowchart illustrating operations and logic implemented by CAM management logic, according to one embodiment.

### DETAILED DESCRIPTION

Embodiments of methods and apparatus for software-assisted sparse memory are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

In accordance with aspects of the embodiments disclosed herein, software guided memory sparsity optimizations are provided. Under one aspect, software requests a region of “sparse memory” of a requested size and a corresponding address range of that size is assigned, but only a fraction of physical memory is reserved. For example, suppose the request is for 1 TB (Terabyte) of memory and the sparsity is 10%. Rather than reserve 1 TB of physical memory, only 100 MB (Megabytes) of physical memory is reserved. Thus, the amount of physical memory that is used for a sparse memory region is a fraction of the address space that is associated with the sparse memory range.

Generally, the intent is not to have all memory reserved as sparse memory. Rather, the approach is to have a new type of memory address space that is mapped into sparse memory. Therefore, the proposed optimization is mapped into a subset of the physical address space and it can be configured by the platform owner. Non-spare memory is accessed using conventional memory access mechanisms, while access to spare memory employ the new mechanisms disclosed herein.

In one aspect, the solutions propose to expand to expand the memory architecture in three areas: (1) Instruction Set Architecture (ISA); (2) Memory hierarchy; (3) Memory controller. The processor (CPU) provides a means exposed to the software stack to enable software to allocate and manage the new type of memory space. In one embodiment, the CPU includes a new mechanism that can be configured either via BIOS, out-of-band (OOB) or a similar mechanism to enable software to identify how much memory can be devoted to sparse memory. The interface will provide to the memory controller (a) the amount or percentage of memory that needs to be devoted for this type of memory (sparse memory); and (b) the maximum amount that applications can allocated for this sparse memory. Generally, the amount or percentage of memory under (a) may be limited by the size of the CAM that the memory controller includes; an increase in the amount or percentage of sparse memory that is available will require a commensurate increase in the size of the CAM.

The CPU also includes a new interface is provided to allow the software stack (e.g., the operating system (OS) on behalf of a given process) to allocate a given amount of memory into the new address space. In alternative non-limiting embodiments, this interface may be implemented using a new ISA or through use of an existing or new Machine State Register (MSR). In one embodiment, the interface will enable the software to provide: (a) the amount of requested memory; (b) the amount of expected sparsity; and (c) the Process Address ID for the process requesting the memory.

Under another aspect, a new software interrupt type is implemented that can be generated by the memory controller when an overflow of a particular address range registered happens. This software interrupt that can be provided to the OS or to a particular PASID. In one embodiment, the software interrupt includes: (a) and address range base address generating the failure; (b) the PASID associated to the range; and (c) the size associated to the memory.

Depending on which hardware component is handling the software interrupt, the OS may need to expose mechanisms to retrieve the virtual address for a particular physical address in order to know what address range caused the failure.

A memory hierarchy scheme is used to implement memory sparsity optimization. The memory hierarchy includes two fundamental constructs: (1) A set of hierarchical Bloom filters; and (2) a memory controller with an associated CAM (content addressable memory). The memory hierarchy scheme also employs a system address decoder (SAD) as a filter to determine whether a given memory access is to a memory address in a sparse memory range that is mapped to a sparse memory region; if it is not, the memory access is memory in a non-sparse memory region and a non-sparse memory access process is performed (e.g., similar to accessing memory in a conventional manner).

The set of hierarchical Bloom filters are associated from a top level 1 (L1) to any nth level n (Ln) that are used to incrementally identify if a given region being accessed from a particular memory read will have zeros or not. For example, L1 can have a bloom filter that tells whether a first level address range derived from a portion of address ‘A’ (@A) is all zeros or not. For example, in one embodiment, the first level is a memory frame level comprising multiple memory pages. L2 could have a bloom filter that tells whether a second smaller address range (e.g., a memory page) has all zeros or not. This paradigm could be repeated at subsequent levels 3-n with ever-decreasing ranges. The bloom filter at Ln tells whether a given memory line (e.g., 64 Bytes) at an address ‘A’ (@A) is all zeros or not. A miss on the bloom filter at any level (access by an applicable portion of the memory address tag of @A) will immediately mean that the memory address being accessed is a zero. Otherwise, the Bloom filter check will proceed to the next level and the process is repeated. If there is a hit at the lowest level (e.g., the cacheline level) this means the cacheline at the address contains none-zero data and is present in a sparse memory region.

In one embodiment, each memory hierarchy will have a system address decoder that is used to identify whether or not a particular address belongs to a memory address range that is mapped into a sparse memory region (called a sparse memory range). On a request arriving at the logic managing that memory hierarchy (e.g., a Caching Agent or L1 cache logic), the logic will use the SAD to decide whether the address belongs to a sparse memory range. In the negative case, the request will continue to the next level in the hierarchy.

In the positive case for memory read, the request will be forwarded to new logic (sparse logic) that is responsible for managing sparse memory access requests. The sparse logic will access the Bloom filter (associated with the hierarchy level) with the memory address tag. In cases where the Bloom filter indicates that the memory line must be zeros, the sparse logic will return zero. Otherwise, the result from the Bloom filter may be a false negative, which will result in the request proceeding to the next level in the hierarchy.

Depending on the level of hierarchy and the type of memory coherency protocol being implemented (e.g., MESI, MESIF etc.) the bloom filters may need to be shared among multiple cores to avoid false positives. In one embodiment, the bloom filters are implemented at the LLC level (e.g., using an LLC agent or other logic) and are used for memory access requests that are required to access system memory (e.g., the requested cacheline is either marked invalid or does not reside in any cache). As an alternative, the bloom filter hierarchy and associated logic may be implemented on the memory controller.

As discussed above, the memory controller is expanded with a SAD used to identify whether a particular address belongs to a physical address memory space that is mapped into the sparse memory. The memory controller includes a CAM that will be accessed with the memory address tag. In case of hit, the CAM will return the real physical address @A′ where @A is stored and the operation will be performed. In case of miss and read, that means that the line was zeros (never written) and not stored in memory DIMMS. Therefore, a read will return 0. In case of a miss and the memory access is a write with a none-zero payload, the memory controller will assign a new physical line @A′, perform the write to @A′ and map the selected memory @A′ to @A in the CAM.

Under an alternative scheme, the SAD is implemented in combination with the Bloom filter hierarchy logic under which prior to entering a Bloom filter search the SAD is used to filter out whether the memory to be accessed is in sparse memory or not. If it is not in sparse memory, the Bloom filter search is not performed.

Generally, the number of entries on the CAM that can be used by a given application (represented by the application's processed address ID (PASID) included in the UPI request) will be limited to what was requested. In case that write for a given application exceeds the requested amount of memory in sparse mode, the memory controller will generate a software interrupt, in one embodiment.

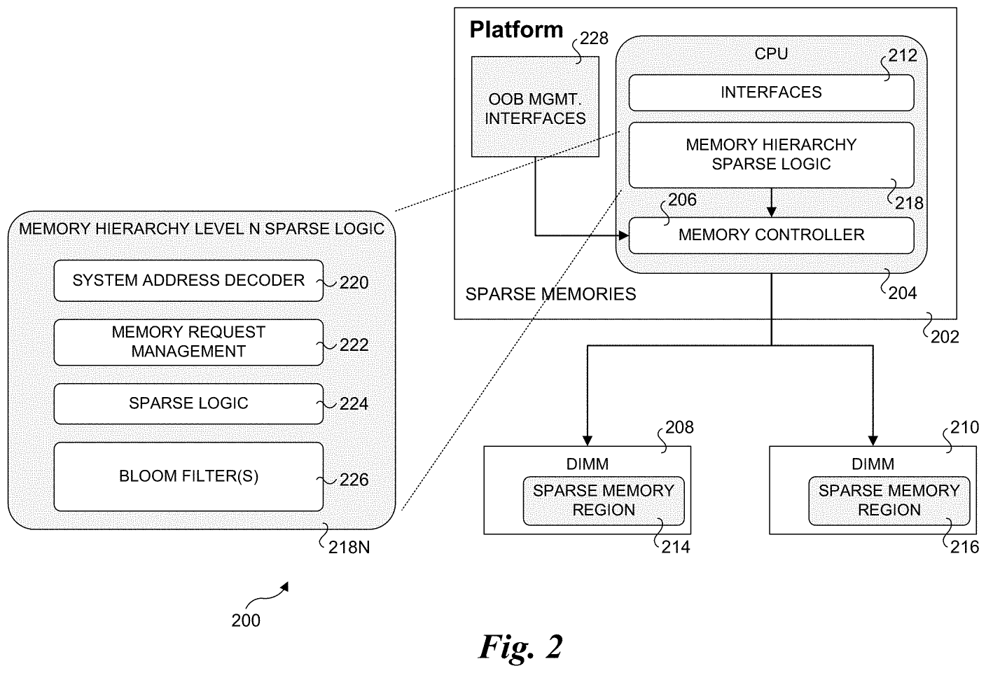

FIG. 2 shows a system architecture 200 for a platform 202 including a CPU 204 with an integrated memory controller 206 coupled to a pair of DRAM DIMMs 208 and 210. The DRAM DIMMs comprise the physical memory for the system (aka system memory), which is mapped into physical and virtual address spaces using existing mechanism. Interfaces 212 allows the software stack (e.g., the operating system (OS) on behalf of a given process) to allocate a given amount of memory into a new address space within the system memory used for sparse memory, such as illustrated by sparse memory regions 214 and 216. In one embodiment, interfaces 212 are implemented via modification to a CPU's ISA. In another embodiment, an existing or new MSR is used. As discussed above, interfaces 212 enable the software (e.g., OS) to provide: (a) the amount of requested memory; (b) the amount of expected sparsity; and (c) the Process Address ID for the process requesting the memory.

CPU 204 also includes memory hierarchy sparse logic 218 which is used to implement m levels in the memory hierarchy. An example of memory hierarchy sparse logic 218N for a given level N is detailed on the left-hand side of FIG. 2. The logic includes a system address decoder 220, memory request management logic 222, sparse logic 224, and bloom filter(s) 226.

Platform 202 also includes OOB management interfaces 228 that enable software (e.g., an OS) to identify how much memory can be devoted to sparse memory. OOB management interfaces 228 will provide to memory controller 206 the amount or percentage of memory to be devoted for sparse memory and the maximum amount that applications can allocated for this sparse memory.

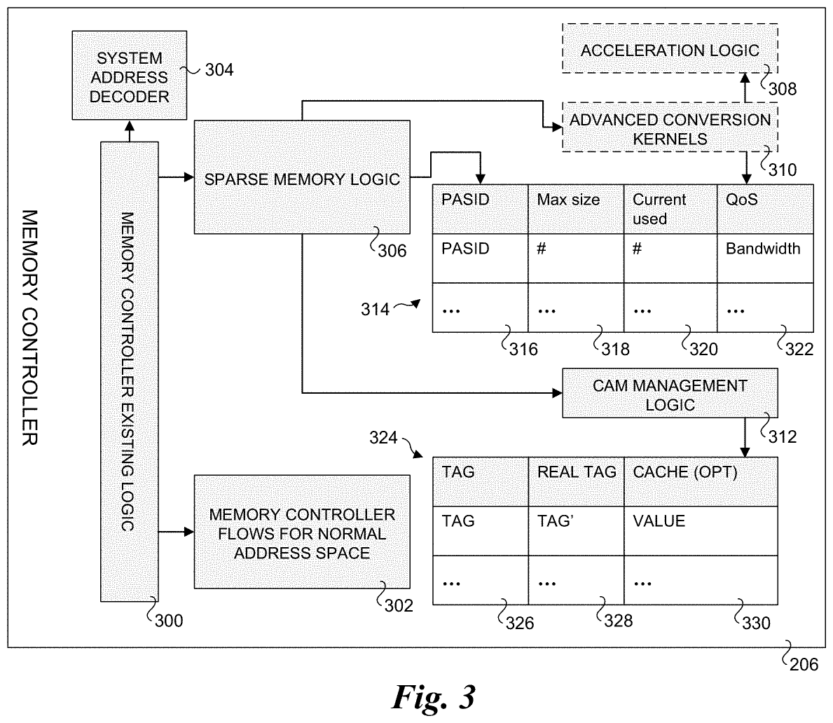

FIG. 3 shows further details of memory controller 206, according to one embodiment. The memory controller includes conventional components and logic depicted as memory controller existing logic 300 and memory controller flows for normal address space 302. System address decoder 304 is configured to implement both conventional SAD operations and novel SAD operations to support access to sparse memory. These conventional components and logic are augmented by new components and logic include sparse memory logic 306, acceleration logic 308 (optional), advanced conversion kernels 310 (optional), and CAM management logic 312. Acceleration logic 308, is used when any of the kernels are implemented in hardware. Advanced conversion kernels 310 capture other operations on memory, via kernels, for potential hardware assist on converting data between formats.

Sparse memory logic 306 is used to access a table 314 including a PASID column 316, a maximum size column 318, a current used column 320, and a QoS (Quality of Service) column 322. When a sparse memory range is allocated/assigned to a process a new entry is added to table 314 that includes the PASID for the process, the maximum size of the sparse memory range. An optional bandwidth may be entered in the QoS column 322. The bandwidth represents the bandwidth to be maintained when accessing sparse memory to meet QoS requirements.

CAM management logic 312 is used to access a table 324 including a tag column 326, a real tag column 328, and an optional cache column 330. Tag column 324 contains logical addresses used by the software. Real tag column 328 contains the physical address at which a non-zero cacheline is stored (a cacheline with a value that is not all zeros).

As discussed above, in some embodiments a hierarchy of Bloom filters is used to detect whether data at different levels of granularity within a sparse memory range is non-zero. A Bloom filter is a space-efficient data structure that is used to test probabilistically whether an element is a member of a set. The simplest form of Bloom filter employs a single hash algorithm that is used to generate bit values for a single row or column of elements at applicable bit positions, commonly referred to as a single-dimension bit vector. Another Bloom filter scheme employs multiple hash algorithms having bit results mapped to a single-dimension bit vector. Under a more sophisticated Bloom filter, the bit vectors for each of multiple hash algorithms are stored in respective bit vectors, which may also be referred to as a multi-dimension bit vector.

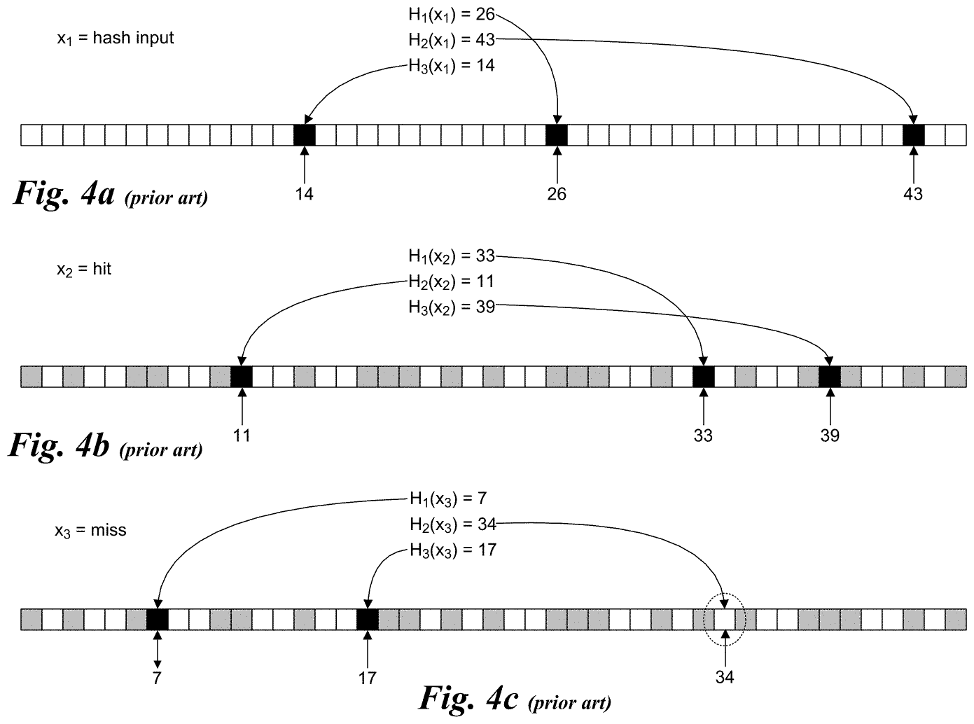

An example of a Bloom filter that is implemented using multiple hash algorithms with bit values mapped into a single-dimension bit vector is shown in FIGS. 4a-4c. In this example, there are three hash algorithms, depicted as H₁(x), H₂(x) and H₃(x), where element x is the input value. For a given input x₁, the result for each of hash algorithms H₁(x₁), H₂(x₁) and H₃(x₁) is calculated, and a corresponding bit is marked (e.g., set to 1) at the bit position corresponding in the hash result. For example, as shown in FIG. 4a, the result of hash function H₁(x₁) is 26, H₂(x₁) is 43, and H₃(x₁) is 14. Accordingly, bits at positions 26, 43, and 14 are set (e.g., the bit values are flipped from ‘0’ (cleared) to ‘1’ (set)). This process is then repeated for subsequent input x₁ values, resulting in the bit vector shown in FIG. 4b, wherein the bits that are set are depicted in gray and black. FIG. 4b also illustrates the result of a hit for input x₂ (bits depicted in black). A hit is verified by applying each of the Bloom filter's hash algorithms using x₂ as the input value (also referred to as a query for element x₂), and then confirming whether there is a bit set at the bit position for each hash algorithm result. For example, if there is a bit set for the position for each hash algorithm result, the outcome is a hit, meaning there is a high probability (depending on the sparseness of the bit vector) that the element xₖ corresponds to a previous input value x₁ for which the hash algorithms were applied and corresponding bits were set.

FIG. 4c shows an outcome of a miss for input x₃. In this case, one or more bit positions in the bit vector corresponding to the hash algorithm results are not set. FIGS. 4b and 4c illustrate a couple of features that are inherent to Bloom filters. First, Bloom filters may produce false positives. This is because the bit vector that is formed by evaluating the hash algorithms against a number of inputs x is a union of the individual results for each input x. Accordingly, there may be a combination of set bit positions that produce a hit result for a test input xᵢ as applied against the Bloom filter's bit vector, while the input xᵢ was not used to generate the bit vector. This is known as a false positive. Another inherent feature of Bloom filters is they do not produce false negatives. If evaluation of an input xᵢ as applied to a Bloom filter's bit vector results in a miss, it is known with certainty that xᵢ is not a member of the set of previous Bloom filter inputs.

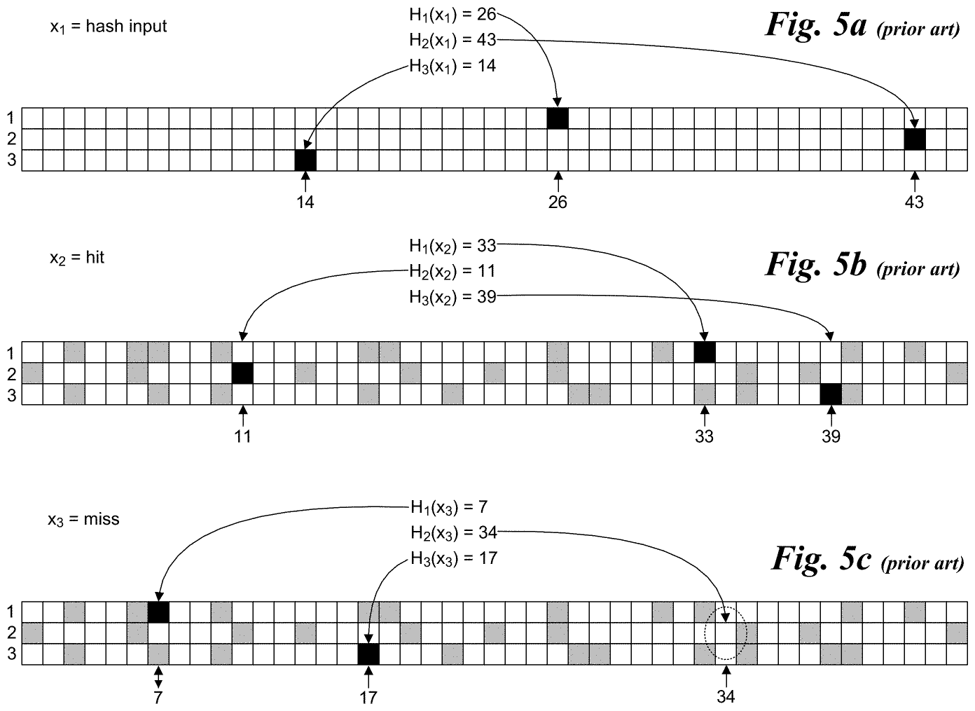

FIGS. 5a-5c illustrate an example of a Bloom filter that maintains a separate table row (and one-dimensional bit vector) for each Bloom filter hash algorithm. Although each row is depicted as having the same length, it is possible that the different hash algorithms will produce bit vectors of different lengths. As hash algorithms are evaluated against input x values (e.g., against x₁ in FIG. 5a), a corresponding bit is set at the bit position for the table row corresponding to the hash algorithm result. As before, input x₂ results in a hit (whether a true hit or a false positive), while input x₃ results in a miss.

Since a hash algorithm may produce the same result for two or more different inputs (and thus set the same bit in the Bloom filter bit vector), it is not possible to remove individual set members (by clearing their bits) while guaranteeing that bits corresponding to other input results will not be cleared. Thus, the conventional Bloom filter technique is one-way: only additional bits may be added to the bit vector(s) corresponding to adding additional members to the set.

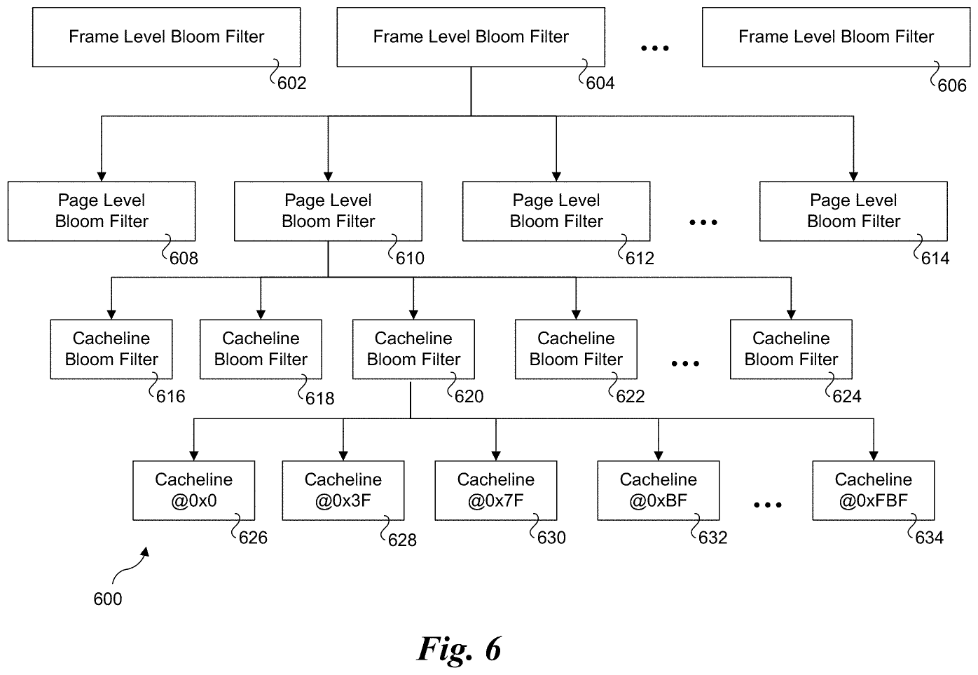

FIG. 6 shows an exemplary Bloom filter hierarchy 600. The three Bloom filter levels include a frame level, a page level, and a cacheline level. The cachelines sit below the cacheline level and are included for illustrative purposes. Generally, the frame level represents an aggregation of memory pages, and as such other terminology may be used in the art to describe such aggregations. The frame level Bloom filters are depicted by Bloom filters 602, 604, and 606. The page level Bloom filters are depicted by Bloom filters 608, 610, 612, and 614. The Bloom filters at the cacheline level are depicted by Bloom filters 616, 618, 620, 622, and 624. The cachelines corresponding to a given cacheline Bloom filter are depicted by cachelines 626, 628, 630, 632, and 634.

In the illustrated example the memory pages have a size of 4K Byes (64×64) and the cachelines have a size of 64 Bytes. Accordingly, each cachelines for a given memory page will have a respective address offset from the base address for the memory page.

The Bloom filters are populated from the bottom of Bloom filter hierarchy 600 in conjunction with writing a non-zero cacheline (i.e., a cacheline that includes at least one ‘1’). Generally, Bloom filter hierarchy 600 may employ some type of indexing scheme to identify each Bloom filter. The indexing scheme will generally, at some level, be tied to the address of the cachelines, and may employ page tables or the like. The non-zero write will populate the Bloom Filters as follows:
1) Hash at the cacheline level and add bit(s) to the bit vector(s) of the cacheline Bloom filter the cacheline is associated with;
2) Hash at the page level and add bit(s) to the bit vector(s) of the page level Bloom filter corresponding to the cacheline in 1); and
3) Hash at the frame level and add bit(s) to the bit vector(s) of the page level Bloom filter corresponding to the page in 2)

Under this scheme adding a non-zero entry to cacheline that adds (a) bit(s) to (a) Bloom filter bit vector(s) in a previously empty cacheline Bloom filter will add (a) bit(s) to an empty page level Bloom filter bit vector(s) corresponding to a memory page containing the cacheline. Similarly, adding (a) bit(s) to an empty page level Bloom filter bit vector(s) corresponding to a memory page containing the cacheline will result in adding (a) bit(s) to an empty frame level Bloom filter bit vector(s) corresponding to the memory page. A characteristic of this approach is that if a frame level Bloom filter check results in a miss there is no need to check either of the page level or cacheline Bloom filters. Similarly, if a page level Bloom filter check results in a miss there is no need to check any of the cacheline Bloom filters associated with that page level Bloom filter.

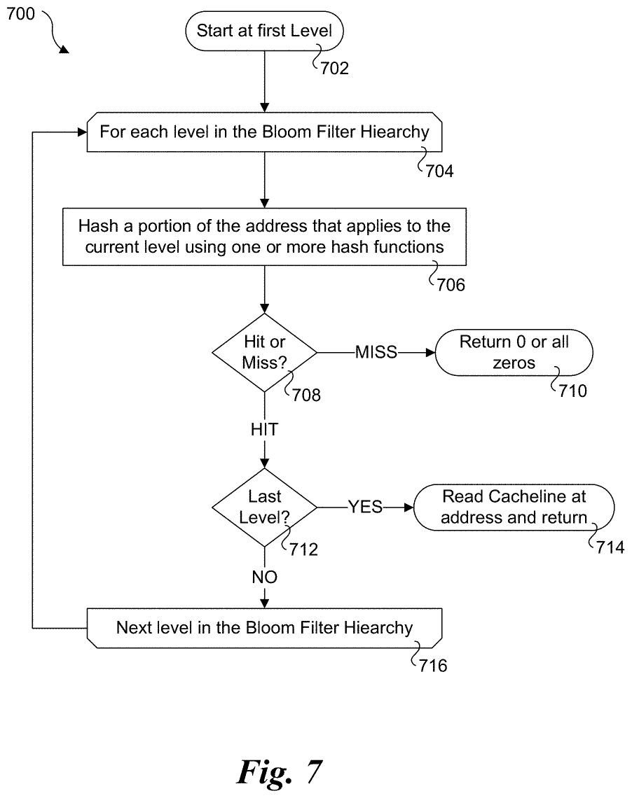

FIG. 7 shows a flowchart 700 illustrating use of a hierarchy of Bloom filters, according to one embodiment. The process begins in a start block 702 at the first level in the hierarchy. As shown by start and end loop blocks 704 and 716, the operations of blocks 706, 708, 710, 712, and 714 are performed for each of one or more levels in the hierarchy. In this example the Bloom filters in the hierarchy have been populated in connection with storing data in one or more sparse memory regions. The example also may use a single row or multiple row Bloom filter.

In a block 706 a portion of the address (e.g., provided via an address tag or the like) is hashed using one or more hash functions associated with the current level. For example, because of the potentially different levels of aggregation at the frame, page, and cacheline levels, different hash functions may be used at different levels. Based on the aggregation level scheme, different portion of the address tag may be used. For example, at the frame level a first portion comprising the highest bit portion of the address may be used, while the middle bits of the address may be used at the page level, and the lowest bits used at the cacheline level. In a decision block 708 a determination is made to whether there is a Hit or Miss. As described above, the data for the cacheline (all zeros) are not actually written to physical memory and there are no bits added to the Bloom filter bit vectors at any level. Thus, a Miss in decision block 708 indicates there is not an entry matching the address, which results in the logic proceeding along the MISS branch to a return block 710 in which a 0 or a cacheline of all zeros is returned.

If the answer to decision block 708 is a HIT, the logic proceeds to a decision block 712 in which a determination if made to whether the current level in the hierarchy is the last level. If the answer is NO, the logic loops back to start loop block 704 to begin the Bloom filter check at the next level. If the answer is YES, then there was Hit at the cacheline level and the logic proceeds to a return block 714 in which the cacheline at the address is read and returned.

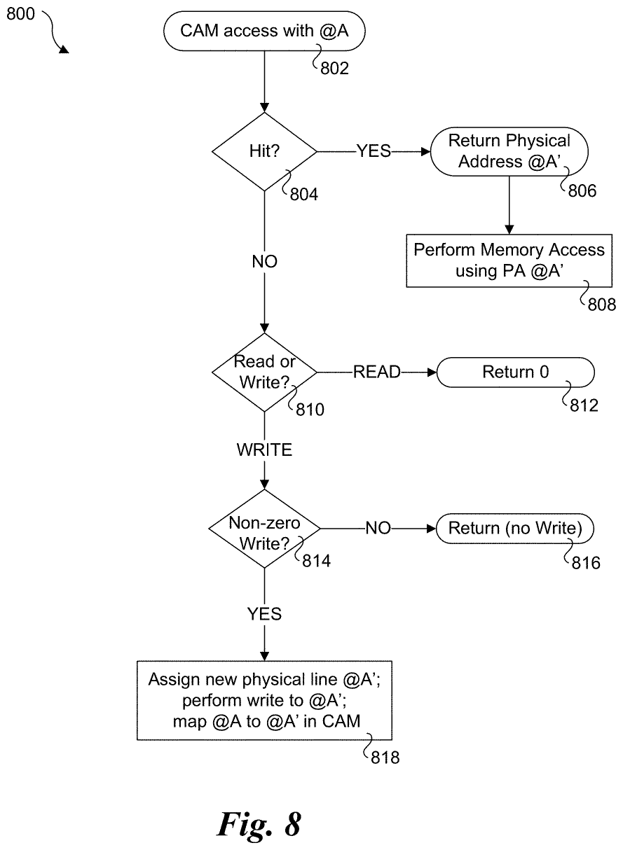

FIG. 8 shows a flowchart 800 illustrating operations and logic implemented by CAM management logic 312, according to one embodiment. The process begins in a start block 802 in which CAM access is provided with the address tag having a logical address for a cacheline (@A). In a decision block 804 a determination is made to whether there is a CAM hit. If there is an entry in table 324, a hit will result. A hit means there is a cacheline at a physical (real) address (@A′) corresponding to the logical address storing non-zero data. Accordingly, when there is a hit the answer to decision block 804 is YES and the logic proceeds to a return block 808 in which the physical address @A′ is returned. The memory controller then performs a memory access using the physical address @A′ in the conventional manner.

If there is not an entry in table 324 the result is a miss, and the logic proceeds along the NO branch to a decision block 810 in which a determination is made to whether the memory access is a memory read or memory write. If it is a memory read, the logic proceeds to a return block 812 in which a 0 (or cacheline with all 0's) is returned. Since only cachelines with non-zero data are written to a sparse memory region there will be no entries added to table 324 for cachelines with values of 0 (all 0's).

If the memory access is a write, the logic proceeds to a decision block 814 in which a determination is made to whether it is a non-zero write (meaning the data for the cacheline has some non-zero values). If the data is a write of all zeros, the answer to decision block 814 is NO and the logic proceeds to a return block 816 under which no data are written to physical memory. If the data for the write includes non-zero data, the logic proceeds to a block 818 in which a new physical cacheline address @A′ is assigned, the write of the non-zero cacheline data is written to the cacheline address @A′, and a new entry is added to the CAM mapping @A to @A′.

Under one embodiment, a bloom filter hierarchy and associated logic may be implemented on a memory controller. For example, in one embodiment the bloom filter hierarchy and logic are implemented by sparse memory logic 306. Under another embodiment, the bloom filter logic is implemented in the memory controller (e.g., by sparse memory logic 306) while the bloom filter hierarchy data are implemented external to the memory controller (e.g., in memory elsewhere on a processor or an SoC or using a portion of system memory). When a bloom filter hierarchy is implemented the use of a CAM is optional.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

As discussed above, various aspects of the embodiments herein may be facilitated by corresponding software and/or firmware components and applications, such as software and/or firmware executed by an embedded processor or the like. Thus, embodiments of this invention may be used as or to support a software program, software modules, firmware, and/or distributed software executed upon some form of processor, processing core or embedded logic a virtual machine running on a processor or core or otherwise implemented or realized upon or within a non-transitory computer-readable or machine-readable storage medium. A non-transitory computer-readable or machine-readable storage medium includes any mechanism for storing or transmitting information in a form readable by a machine (e.g., a computer). For example, a non-transitory computer-readable or machine-readable storage medium includes any mechanism that provides (i.e., stores and/or transmits) information in a form accessible by a computer or computing machine (e.g., computing device, electronic system, etc.), such as recordable/non-recordable media (e.g., read only memory (ROM), random access memory (RAM), magnetic disk storage media, optical storage media, flash memory devices, etc.). The content may be directly executable (“object” or “executable” form), source code, or difference code (“delta” or “patch” code). A non-transitory computer-readable or machine-readable storage medium may also include a storage or database from which content can be downloaded. The non-transitory computer-readable or machine-readable storage medium may also include a device or product having content stored thereon at a time of sale or delivery. Thus, delivering a device with stored content, or offering content for download over a communication medium may be understood as providing an article of manufacture comprising a non-transitory computer-readable or machine-readable storage medium with such content described herein.

Various components referred to above as processes, servers, or tools described herein may be a means for performing the functions described. The operations and functions performed by various components described herein may be implemented by software running on a processing element, via embedded hardware or the like, or any combination of hardware and software. Such components may be implemented as software modules, hardware modules, special-purpose hardware (e.g., application specific hardware, ASICs, DSPs, etc.), embedded controllers, hardwired circuitry, hardware logic, etc. Software content (e.g., data, instructions, configuration information, etc.) may be provided via an article of manufacture including non-transitory computer-readable or machine-readable storage medium, which provides content that represents instructions that can be executed. The content may result in a computer performing various functions/operations described herein.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. An apparatus, comprising:
a memory controller configured to be coupled to and provide access to memory contained in one or more memory devices; and
circuitry and logic to:
implement one or more memory ranges in a memory space of the memory as sparse memory ranges;
receive a memory access request with an associated address;
determine whether the address is within a sparse memory range; and
when the address is within a sparse memory range, perform sparse memory access operations to access memory in the sparse memory range.

2. The apparatus of claim 1, wherein the circuitry and logic include a system address decoder (SAD) that is configured to encode memory addresses to sparse memory ranges and non-sparse memory, and wherein the SAD is used to determine whether the address for the memory access request is within a sparse memory range.

3. The apparatus of claim 1, further comprising an interface to configure a memory address space for the memory into one or more sparse memory ranges and non-sparse memory.

4. The apparatus of claim 1, wherein the apparatus comprises a processor including a plurality of cores, further comprising an interface to enable software executing on one or more of the plurality of cores to request a portion of a memory address space for the memory be allocated to a new sparse memory region or allocated to an existing sparse memory region.

5. The apparatus of claim 4, wherein the interface enables the software to provide:
an amount of memory to be used as sparse memory; and
an expected amount of sparsity for the data to be stored in the allocated sparse memory.

6. The apparatus of claim 1, wherein the memory access request is a memory read request, and wherein when the address is within a sparse memory range, the circuitry and logic is configured to determine whether data at an address associated with the memory read request are all zeros.

7. The apparatus of claim 6, wherein the circuitry and logic include a hierarchy of bloom filters that are used to determine whether the data at the associated address are all zeros.

8. The apparatus of claim 1, wherein the memory controller includes a content addressable memory (CAM) that is configured to:
receive a memory address tag corresponding to the address associated with a memory access request; and
return a physical address corresponding to the memory address tag when a CAM lookup of the memory address tag is a hit.

9. The apparatus of claim 8, wherein the memory controller is further configured to:
determine the CAM lookup is a miss; and
when the memory access request is a memory write including one or more non-zero bits,
assign a new cacheline at a new physical address within a sparse memory region;
perform the memory write to the new cacheline; and
add a new entry to the CAM mapping the new physical address to the address associated with the memory access request.

10. The apparatus of claim 8, wherein the memory controller is further configured to:
determine the CAM lookup is a miss; and
when the memory access request is a memory read, return a 0 or a cacheline with all zeros.

11. A method implemented on a platform including a processor having a memory controller coupled to memory, comprising:
configuring an address space for the memory into one or more sparse memory regions and non-sparse memory;
determining whether memory access requests are for accessing memory within a sparse memory region; and
when a memory access request is for accessing memory within a sparse memory region, performing operations associated with accessing memory in the sparse memory region; otherwise
performing non-sparse memory access operations to access memory from non-sparse memory.

12. The method of claim 1, wherein operations associated with accessing memory in the sparse memory region include:
for a memory read request having an associated address,
determining when data at the associated address are all zeros; and
returning a zero or a cacheline with all zeros when the data at the associated address are all zeros.

13. The method of claim 12, further comprising:
implementing a content address memory (CAM) with a plurality of entries comprising an address tag and a physical address;
determining, using the address associated with the read request as an address tag whether there is a CAM hit; and
when there is not a CAM hit, returning a zero or a cacheline that is all zeros.

14. The method of claim 12, further comprising:
implementing a hierarchy of bloom filters having two or more levels;
encoding bloom filters within the hierarchy of bloom filters to provide indicia whether addresses associated with memory read requests correspond to data in a sparse memory region containing all zeros; and
employing the hierarchy of bloom filters to determine when data at the address associated with a memory read request are all zeros.

15. The method of claim 11, further comprising:
enabling software running on the platform to request a portion of a memory address space for the memory be allocated to a new sparse memory region or assigned to an existing sparse memory region.

16. A system, comprising:
one or more memory devices containing memory;
a processor including:
a plurality of cores;
a memory controller configured to be coupled to and provide access to memory contained in the one or more memory devices; and
circuitry and logic to:
implement one or more memory ranges in a memory space of the memory as sparse memory ranges;
receive a memory access request with an associated address originating from software executing on a processor core;
determine whether the address is within a sparse memory range; and
when the address is within a sparse memory range, perform sparse memory access operations to access memory in the sparse memory range; otherwise
perform non-sparse memory access operations to access memory associated with the address.

17. The system of claim 16, wherein the processor includes an interface to enable software executing on one or more of the plurality of cores to request a portion of a memory address space for the memory be allocated to a new sparse memory region or allocated to an existing sparse memory region.

18. The system of claim 16, wherein the memory access request is a memory read request, and wherein when the address is within a sparse memory range, the circuitry and logic is configured to determine whether data at an address associated with the memory read request are all zeros.

19. The system of claim 16, wherein the circuitry and logic configured to determine whether data at an address associated with the memory read request are all zeros comprises a hierarchy of bloom filters.

20. The system of claim 16, wherein the circuitry and logic configured to determine whether data at an address associated with the memory read request are all zeros comprises a content addressable memory (CAM).
